(19) United States
(12) Patent Application Publication
(10) Pub. No.: US 2007/0121281 A1
(43) Pub. Date: May 31, 2007

(54) Voltage regulator module support

(76) Inventors: Vic Hong Chia, Plano, TX (US); Paul Wirtzberger, Greenville, TX (US); Michelle J. M. Austin, Frisco, TX (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/287,795

(22) Filed: Nov. 28, 2005

(51) Int. Cl. H05K 5/00

(52) U.S. Cl. 361/683

(57) ABSTRACT

In accordance with one embodiment, the present invention relates to a support structure for an electronic component, such as a voltage regulator module for a computer device. The exemplary support structure has a body and a leg extending askew from the body, the leg and body cooperating to define a receiving region for receiving the electronic component. The leg has a resilient securement portion that is configured to releasably engage with an electronics substrate.

### BACKGROUND

The present invention, in a general sense, relates to a support structure for an electronic component, such as a computer component found in a computer device.

In computer devices, power distribution is an important concern, because various components of such devices often operate at different power levels and types. Accordingly, most computer devices include power supply circuitry that distributes and conditions an input power—which is generally 110 or 220 Volt (V) alternating current (ac) power—to more appropriate direct current (dc) power levels for the various computer components, such as memory, graphics circuitry, storage media, etc. Of particular concern, the processor of a computer device benefits from well-conditioned power having a relatively constant power level without transient voltages.

To provide the processor with well-conditioned power, computer devices generally include a voltage regulator module (VRM) that acts as a gatekeeper between the power supply circuitry and the processor. For example, VRMs further condition power from the power supply circuitry, to prevent transient voltages from reaching the processor and, in turn, possibly damaging the processor or negatively impacting the computer device's performance, for instance.

In the past, VRMs have been mechanically and electrically coupled to the motherboard on which the processor is disposed via a connector-pin engagement. That is, conductive pins extending from the VRM engage with a corresponding connection portion on the motherboard, thus electrically and mechanically coupling the VRM to the motherboard. Accordingly, these pins bare much of mechanical loading placed on the VRM, leaving them susceptible to damage and, in certain instances, unable to provide sufficient support to pass quality-control tests, such as impact and vibration tests. For increased robustness, a few traditional computer devices employ a metal bracket structure to support the VRM. However, these metal assemblies are susceptible to shorting and, furthermore, require the use of screws and/or nuts that rely on machine tools for mounting to a motherboard. Resultantly, these traditional support structures increase the complexity of the manufacturing process and the costs of manufacture. Moreover, such traditional support structures consume a relatively large amount of valuable surface space on the motherboard, increasing the overall costs of the computer device. Further still, traditional VRM support structures are dedicated in design to a specific VRM type, thus hindering the ability to modify or change the underlying VRM without changing or modifying the VRM support. This rigidity in design can lead to increased lead-times that, as one among many negative impacts, can lead to delays in manufacturing.

Therefore, there exists a need for improved electronic component support techniques.

### BRIEF SUMMARY OF THE INVENTION

In accordance with one embodiment, the present invention relates to a support structure for an electronic component, such as a voltage regulator module for a computer device. The exemplary support structure has a body and a leg extending askew from the body, the leg and body cooperating to define a receiving region for receiving the electronic component. The leg has a resilient securement portion that is configured to releasably engage with an electronics substrate.

### BRIEF DESCRIPTION OF THE DRAWINGS

Advantages of one or more disclosed embodiments may become apparent upon reading the following detailed description and upon reference to the drawings in which:

FIG. 1 diagrammatically illustrates a computer system, in accordance with an exemplary embodiment of the present technique;

FIG. 2 diagrammatically illustrates a processor-based device, in accordance with an exemplary embodiment of the present technique;

FIG. 3 is a top perspective view of a support structure for supporting an electronic component, wherein the support structure is in a disengaged position with respect to a printed circuit board, in accordance with an embodiment of the present technique; and

FIG. 4 is a bottom perspective view of the support structure of FIG. 3, wherein the support structure is in an engaged position with respect to the printed circuit board.

### DETAILED DESCRIPTION

One or more specific embodiments of the present technique will be described below. In an effort to provide a concise description of these embodiments, not all features of an actual implementation are described in the specification. In view of this, it should be appreciated that in the development of any such actual implementation, as in any engineering or design project, numerous implementation-specific decisions will be made to achieve the developers' specific goals, such as compliance with system-related and business-related constraints, which can vary from one implementation to another. Moreover, it should be appreciated that such a development effort can be complex and time consuming, but would remain a routine undertaking of design, fabrication, and manufacture for those of ordinary skill having the benefit of this disclosure. In view of this, it should be noted that illustrated embodiments of the present technique throughout this text represent a general case.

In accordance with certain embodiments, the present technique provides a support structure for supporting a voltage regulator module (VRM) coupled to a motherboard of a computer device. As discussed further below, this exemplary support structure facilitates tool-less coupling of the support structure to the motherboard, resultantly reducing manufacturing times and costs for computer devices. Moreover, the exemplary support structure consumes less circuit board space then traditional designs and, in turn, allows for placement of additional components on the motherboard. As yet another benefit, certain embodiments of the present technique relate to a support structure formed of a polycarbonate material that reduces the likelihood of shorting between the VRM and the support structure. However, prior to continuing, it is again worth noting that the following discussion is merely related to exemplary embodiments, and that the present technique is applicable to securing a host of electronic components to various kinds of electronic substrates—not just the securing of VRMs to printed circuit boards.

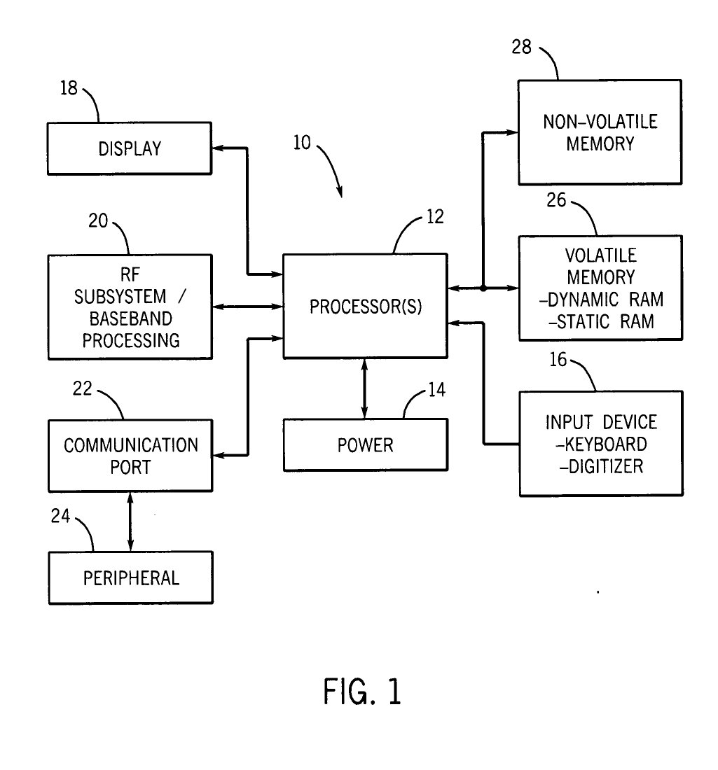

Turning now to the drawings, and referring initially to FIG. 1, a block diagram depicting a computer system having an exemplary processor-based device 10 is illustrated. This device 10 may be any of a variety of different types, such as a computer device, pager, cellular telephone, personal organizer, control circuit, etc. In a typical processor-based device, a processor 12, such as a microprocessor, controls many of the functions of the device 10, often in cooperation with software.

For operating power, the computer device is in communication with a power source 14. For instance, if the device 10 is portable, the power source 14 can be permanent batteries, replaceable batteries, and/or rechargeable batteries. Of course, the power supply 14 may also include an ac adapter that rectifies incoming ac power to dc power. In fact, the power supply 14 may also include a dc adapter that conditions incoming dc power to a more appropriate dc level, facilitating powering of the device through a vehicle's cigarette lighter, for instance.

Various other devices may be coupled to the processor 12, depending upon the functions that the device 10 performs. For instance, a user interface 16 may be coupled to the processor 12. As examples, the user interface 16 can be an input device, such as buttons, switches, a keyboard, a light pen, a mouse, and/or a voice recognition system, for instance. To further facilitate interaction with a user, the processor can be coupled to a display 18, such as an LCD display, a CRT, LEDs, and/or an audio display. Furthermore, a radio frequency (RF) subsystem/baseband processor 20 may also be coupled to the processor 12. The RF subsystem/baseband processor 20 may include an antenna that is coupled to an RF receiver and to an RF transmitter. A communication port 22 can also be coupled to the processor 12. The exemplary communication port 22 is adapted for communications with a peripheral device 24, such as a modem, a printer, or a computer, for instance, or to a network, such as a local area network or the Internet.

Because the processor 12 controls the functioning of the device 10 generally under the control of software programming, memory is coupled to the processor 12 to store and facilitate execution of the software program. For instance, the processor 12 may be coupled to volatile memory 26, which may include dynamic random access memory (DRAM), static random access memory (SRAM), Double Data Rate (DDR) memory, etc. The processor 12 may also be coupled to non-volatile memory 28. The non-volatile memory 28 may include a read only memory (ROM), such as an EPROM or Flash Memory, to be used in conjunction with the volatile memory. The size of the ROM is typically selected to be just large enough to store any necessary operating system, application programs, and fixed data. The volatile memory 26, on the other hand, is typically quite large so that it can store dynamically loaded applications. Additionally, the non-volatile memory 28 may include a high capacity memory such as a disk drive, tape drive memory, compact disc (CD) ROM drive, digital video (DVD), read/write CD ROM drive, universal serial bus (USB) drive, and/or a floppy disk drive.

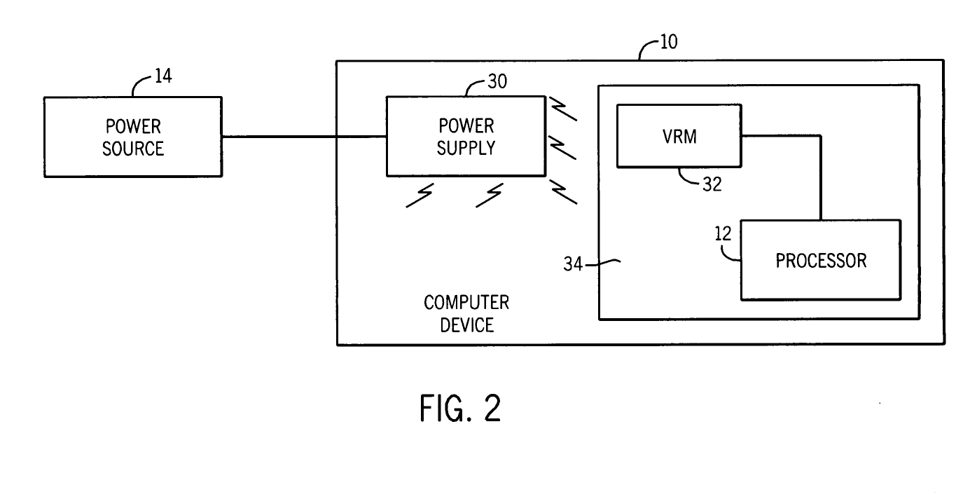

Focusing on power distribution in a computer device, FIG. 2 diagrammatically illustrates an exemplary pathway through which operating power is provided to the processor 12. As discussed above, operating power is initially provided by the power source 14, whether ac power or dc power, depending on the kind of power source 14. Power from the power source 14, however, is not directly routed to the various components of the computer device 10, because these components often operate at various levels and types of power generally different from that provided by the power source 14. Accordingly, the computer device 10 has a power supply 30 that includes both conditioning and distribution circuitry, to provide appropriate levels of power to the various components in the device. By way of example, the power supply 30 can provide dc power at a first voltage level to the memory components while providing ac or dc power at a second, different voltage level to the disk-drive components.

The processor 12, however, benefits from power that is better conditioned, e.g., less likely to present transient voltages and oscillations in level, than is generally supplied to the remainder of the computer components. Accordingly, power to the processor 12 is routed through a voltage regulator module (VRM) 32 that well-conditions the power provided to the processor 12, substantially reducing or preventing transient voltages, voltage fluctuations and the like from affecting the processor 12. In effect, the VRM 32 acts as a gatekeeper for the power provided to the processor 12. As illustrated in FIG. 2, both the VRM 32 and the processor 12 are mechanically coupled to and electrically in communication with a motherboard 34. However, it is worth noting that the VRM 32 and processor 12 may be mechanically coupled to various components and not just a printed circuit board or motherboard. For example, the VRM 32 may be mechanically coupled to various types of electronics substrates that in some fashion facilitate power communication between the VRM 32 and the processor 12.

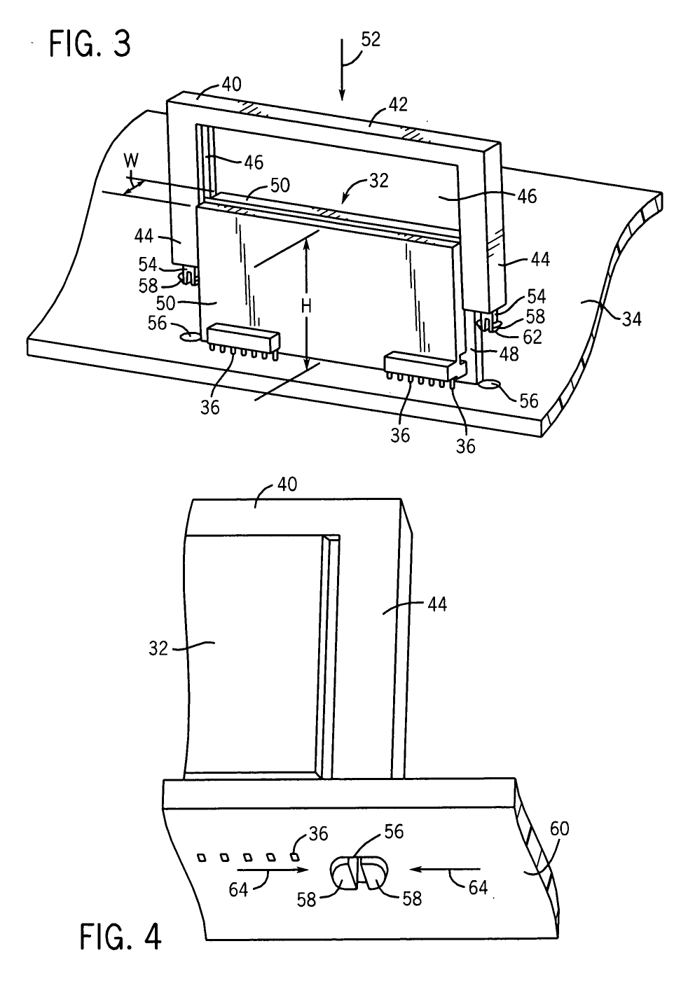

As best illustrated in FIG. 3, the electrical and initial mechanical engagement between the VRM 32 and the motherboard 34 is provided by connector pins 36 extending from the VRM 32. In the exemplary embodiment, these pins 36 engage with corresponding connection portions (e.g., female connectors or receptacles) configured to receive the pins 36 and located on the motherboard 34. To communicate with the processor 12, these pins 36, via the connection portions, are coupled to etched electrical pathways located on the motherboard 34 and electrically coupled to the processor 12 and the power supply 30.

To conserve valuable board space—on which various additional electronic components may be placed and electrically coupled—the exemplary VRM 32 is mounted in a generally vertical position with respect to the motherboard 34. That is, the height (H) of the VRM 32 with respect to the motherboard 34 is greater than the width (W) of the VRM 32. Accordingly, the footprint of the VRM 32 on the motherboard 34 is minimized, again, freeing up valuable real estate on the motherboard 34. Vertical placement of the VRM 32, however, tends to increase the size of moment forces borne by the pins 36, making them susceptible to damage, for instance.

In the exemplary embodiment, a support structure 40 provides additional support to the vertically mounted VRM 32, particularly reducing the moment forces borne by the pins 36. The exemplary support structure 40 has a body 42 and a pair of legs 44 that extend from the body 42. As illustrated, the body 42 and legs 44 cooperate to define a C-shaped, or U-shaped, profile for the support structure 40, and to define a receiving region 46 that is configured to receive the VRM 32. In other words, the body 42 and legs 44 define three inner sides or support members, which can engage three sides (e.g., card edges) VRM 32. Advantageously, the legs 44 can include grooves, slots, rails, or channels 46 that are open to the receiving portion and that are configured to capture a portion of the VRM 32 to support the VRM 32. For example, the channels 44 are configured to receive opposite sides or edges of a printed circuit board 48 on which the VRM circuitry 50 is disposed. Accordingly, when the support structure 40 is placed over the VRM 32 (as represented by directional arrow 52), the engagement between the printed circuit board 48 and the channels 44 facilitates a transfer of the moment loads on the VRM 32 to the support structure 42. Additionally, the abutment between the VRM 32 and the body 42 of the support structure 40, when the body is fully seated, prevents separation of the VRM 32 from the motherboard 34. In some embodiments, the body 42 also may include a groove, slot, rail, or channel to fit about a top side (e.g., card edge) of the VRM 32. Furthermore, certain embodiments of the body may have a slight curvature, which flattens out and acts as a downward spring as the support structure 40 is coupled to the motherboard 34.

To mount the support structure 40 to the motherboard 34, the support structure 40 includes a securement portion that has tool-free mounts or resilient fastener members 54 extending from the legs 44. These resilient fastener members 54 are cooperative with apertures 56 in the motherboard 34 to block separation of support structure 40 from the motherboard 34. Specifically, as best illustrated in FIG. 4, each resilient fastener member 54 includes a tabbed portion 58 having a shoulder that is configured to engage with the underside 60 of the motherboard 34. Accordingly, when the support structure 40 fully seats with the motherboard 34, the resilient fastener members 54 extend through the apertures 56, with the tabbed portions 58 extending beyond the aperture 56 and abutting against the underside 60 of the motherboard 34. For example, the tabbed portions 58 may include hooks, snaps, latches, or other tool-free fasteners. In alternative embodiments the support structure 40 may include female fasteners, while the motherboard 34 includes male fasteners.

The engagement and disengagement of the exemplary support structure 40 with the motherboard 34 is facilitated by the moveablity of the resilient fastener members 54. For example, as the support structure 40 is brought into engagement with the apertures 56 of the motherboard 34, the tabbed portions 58 are compressed toward one another by the engagement of slopped surfaces on the tabbed portions 58 with the aperture 56. That is, the slopped surfaces act as camming surfaces that drive the resilient fastener members 54 toward one another. This compression decreases the width of the securement portion and allows the apertures 56 to receive the tabbed portions 58. However, as the tabbed portions 58 emerge from the apertures 56, the resiliency of the resilient fastener members 54 causes them to return back to the unbiased state, and, thus, causes the tabbed portions 58 to extend beyond the periphery of the apertures 56. In turn, the shoulders of the tabbed portions 58 abut against the underside 60 of the motherboard, blocking separation of the support structure 40 and motherboard 34 with respect to one another. Conversely, separation of the support structure 40 and the motherboard 34 is facilitated by compression of the resilient members 54, as represented by directional arrows 64 of FIG. 4. Advantageously, the exemplary support structure 40 facilitates tool-less insertion and removal, thus reducing the costs of manufacture and assembly in comparison to traditional assemblies. In other embodiments, the resilient fastener members 54 may be replaced or supplemented with boss members, keyhole slots, hooks, latches, snap-fit mechanisms, leveraging mechanisms, springs, and so forth.

When assembled, the support structure provides a robust mechanism for transferring moment loads on the VRM 32 to remainder of the computer device, particularly to the motherboard 34 and the support structure. This transference, in turn, mitigates the likelihood of damage to the pins 36 and provides better compliance with quality-control tests, such as impact and vibration tests. Moreover, the abutment of the VRM 32 with the secured body 42 of the support structure 40 prevents separation of the VRM from the motherboard and, thus, ensures a good electrical connection between these two structures. In fact, the body 40 can provide an axial force that biases the pins 36 toward engagement with the motherboard 34. Furthermore, the support structure 40 can be formed of an electrically insulative material, such a polycarbonate. Advantageously, the use of an insulative material, like a polycarbonate, reduces the likelihood of shorting between the VRM 32 and the support structure 40. In other embodiments, the support structure 40 may include a metal inner frame and an outer insulative coating or layer. Thus, the metal inner frame increases the rigidity and structural support of the structure 40, while the outer insulative coating reduces the likelihood of electrical shorting. The illustrated support structure 40 is a single piece construction, which reduces costs and complexity. However, certain embodiments of the support structure 40 may have variable dimensions, e.g., via hinged or slidable joints between the body 42 and the legs 44.

Prior to concluding, it is again worth noting the present technique is not limited to the embodiments described above. Indeed, the present technique is applicable to the securement and/or the supporting of any number of electronic components in any number of devices. Accordingly, the appended claims are not intended to be limited to the examples and embodiments described above.

What is claimed is:

1. An electronic component support structure, comprising:
a body having a leg extending askew therefrom, wherein the leg is cooperative with the body to at least partially define a region configured to receive an electronic component, and the leg has a resilient securement portion configured to releasably engage with an electronics substrate.

2. The electronic component support structure as recited in claim 1, comprising a channel disposed in the leg, open to the receiving region, and configured to receive a further electronics substrate of the electronic component.

3. The electronic component support structure as recited in claim 1, comprising a plurality of legs, including the leg, extending askew from the body, wherein the plurality of legs and the body cooperate to define a generally C-shaped profile.

4. The electronic component support structure as recited in claim 1, wherein the resilient securement portion comprises a pair of cantilevered members, the cantilevered members having tabbed portions extending oppositely with respect to one another.

5. The electronic component support structure as recited in claim 4, wherein the tabbed portions are configured to engage with the electronics substrate to block separation of the support structure with respect to the electronics substrate.

6. The electronic component support structure as recited in claim 1, wherein the leg and body comprise a polycarbonate material.

7. A system for securing a voltage regulator module, the system comprising:
a voltage regulator module electrically and mechanically coupled to a printed circuit board; and
a support structure at least partially circumscribing the voltage regulator module, and including a resilient fastener member cooperative with the printed circuit board to block separation of the support structure and the printed circuit board with respect to one another.

8. The system as recited in claim 7, wherein the voltage regulator module is disposed generally vertical with respect to the printed circuit board.

9. The system as recited in claim 7, wherein the voltage regulator module is directly coupled to a motherboard of a processor-based device.

10. The system as recited in claim 7, wherein the height of the voltage regulator module with respect to the printed circuit board is greater than the width of the voltage regulator module.

11. The system as recited in claim 7, wherein the voltage regulator module comprises a further printed circuit board, and wherein the support structure includes a channel configured to receive an edge portion of the further printed circuit board.

12. The system as recited in claim 7, wherein the support structure comprises an electrically insulative material.

13. The system as recited in claim 7, wherein the resilient member comprises a tabbed portion, the tabbed portion engaging with the printed circuit board on a side opposite the side closest to the voltage regulator module.

14. A computer system, comprising:
a motherboard having a processor disposed thereon;
a voltage regulator module disposed on a printed circuit board, and mechanically and electrically coupled to the motherboard; and
a support structure at least partially circumscribing the voltage regulator module, and having at least one resilient fastener member configured to engage with the motherboard to block separation of the support structure and the motherboard with respect to one another and having a channel configured to receive a portion of the printed circuit board.

15. The computer system as recited in claim 14, wherein the printed circuit board is oriented edgewise with respect to the motherboard.

16. The computer system as recited in claim 15, wherein the height of the printed circuit board with respect to the motherboard is greater than the width.

17. The computer system as recited in claim 14, wherein the at least one resilient member comprises a tabbed portion configured to engage with the motherboard on a side opposite the voltage regulator module.

18. The computer system as recited in claim 14, wherein the support structure consists essentially of a polycarbonate material.

19. A method for securing a voltage regulator module to a printed circuit board, comprising:
capturing a portion of voltage regulator module coupled to the printed circuit board with a support structure; and
resiliently securing the support structure with the printed circuit board to support the voltage regulator module with the printed circuit board with respect to one another.

20. The method as recited in claim 19, comprising supporting the voltage regulator module in a generally vertical position with respect to the printed circuit board.

21. The method as recited in claim 19, wherein capturing comprises surrounding an edge portion of the voltage regulator module in a channel located in the support structure.
